(19) United States
(12) Patent Application Publication
(10) Pub. No.: US 2026/0223322 A1
(43) Pub. Date: Jul. 30, 2026

(54) MODULAR ADAPTER FOR IMMERSION COOLING

(71) Applicant: HEWLETT PACKARD ENTERPRISE DEVELOPMENT LP, Spring, TX (US)

(72) Inventors: David Allen Moore, Tomball, TX (US); Steven Dale Webster, Montgomery, TX (US); Keith Allen Sauer, Spring, TX (US); Austin Edward Rodriguez, The Woodlands, TX (US)

(21) Appl. No.: 19/041,099

(22) Filed: Jan. 30, 2025

(51) Int. Cl. H05K 7/20

(52) U.S. Cl. CPC H05K 7/20272; H05K 7/20236; H05K 7/20263; H05K 7/20281; H05K 7/203; H05K 7/20327; H05K 7/20381

(57) ABSTRACT

An information processing system comprises a system board having electronic components and a chassis supporting the system board. The chassis includes fan shroud attachment points configured to receive a fan shroud attached thereto. A modular adapter for immersion cooling includes a support having a base and a pair of side arms. The side arms are configured to couple to the chassis at the fan shroud attachment points in lieu of the fan shroud. A manifold is coupled to the base and a pump is operatively coupled to the manifold. The pump is configured to move a flow of liquid coolant from a pool through the manifold when the information processing system is immersed in a pool of liquid coolant. The manifold is configured to output the flow of the liquid coolant back into the pool as one or more output streams.

Information processing systems, (e.g., servers) generate heat during operation and, if the heat is not dissipated or cooling is not provided, damage or malfunctions can occur to various components within the system. One way to provide cooling to a system is through the use of airflow through the system, such as by using fans disposed within the system, with airflow over components providing cooling. Another way to provide cooling to a system is through the use of liquid cooling, where coolant liquids flowing over components remove heat from the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a modular adapter for immersion cooling.

FIG. 2 is a perspective view of a modular adapter for immersion cooling.

FIG. 3 is a front elevation view of the modular adapter of FIG. 2.

FIG. 4 is a rear elevation view of the modular adapter of FIG. 2.

FIG. 5 is a bottom perspective view of the modular adapter of FIG. 2.

FIG. 6 is a bottom plan view of the modular adapter of FIG. 2.

FIG. 7 is a perspective view of an information processing system including the modular adapter of FIG. 2.

FIG. 8 is a method for adapting a system to include a modular adapter.

### DETAILED DESCRIPTION

Information processing components, such as CPUs, are increasing in power and heat generation, which is making it increasingly difficult to efficiently cool the system via airflow. As heat generation increases, greater volumes of air must be moved through the system to achieve the same level of cooling. The increase in air volume through the system results in increased power consumption and increased noise. In addition, as the amount of air to be moved through the system increases, costs for the various components, including fans, heat sinks, etc. also increase. In addition, in some circumstances, air cooling is not a viable option for providing cooling to a system.

An alternative means by which an information processing system may be cooled is liquid cooling, in which liquid materials are used as a coolant to remove heat from a system. One form of liquid cooling is direct liquid cooling (DLC), in which liquid coolant flows through a system using tubes/pipes, and heat is extracted from heat generating components of the system into the liquid coolant via cold plates coupled to the components. DLC is often used in information processing systems having high component density, such as supercomputers or high-performance compute systems, where there are multiple components generating high amounts of heat. While DLC is highly efficient at removing heat from a system, it also has a high cost due to the addition of further components, such as cold plates and coolant pipes, to the system, with such components often being customized for each particular system.

Another form of liquid cooling is immersion cooling, in which a tank is at less partially filled with a liquid coolant and electronic components of a system are immersed within the liquid. Heat is extracted from heat generating components of the system directly into the coolant, which is then circulated through the tank by, e.g., being pumped to a heat exchanger, where the heat is transferred to a cooling circuit, allowing the coolant to re-enter the tank.

It is possible to design a new computing system specifically optimized from the ground up for immersion cooling. However, generating and validating such a new system design can be costly and difficult. Furthermore, such a special-purpose system may have a relatively limited market segment, i.e., it may be limited only to those who use immersion cooling. Accordingly, it may be preferable if an existing information processing system originally designed for use in some other context, such as for air cooling could be used in an immersion cooling environment, as this could save costs by avoiding the need for a new system design and also could allow the same general design to cover multiple market segments (i.e., both air cooling and immersion cooling).

However, existing information processing systems that were originally designed for air cooling may not be well optimized for immersion cooling. In general, an air-cooled system can be relatively easily converted to state in which it can be used in an immersion cooling tank, for example by removing the air-cooling specific components, such as fans, heat sinks, and baffles, as well as by removing components incompatible with immersion, such as thermal pasts, stickers, or the like. This form of conversion may be referred to herein as a baseline conversion because it represents a minimal conversion to ready the system for immersion. While the aforementioned baseline conversion can relatively easily allow for an air-cooled system to be converted for use in the immersion cooling tank, the resulting system is not well optimized for immersion cooling and thus some of the benefits which may be possible with immersion cooling may not be fully realized. For example, it may be desirable to provide additional cooling to certain components, such as a CPU, beyond the cooling that occurs when the system which has been converted in the manner described above is immersed in an immersion tank.

To address these and other issues, examples disclosed herein relate to modular adapters which can optimize an information processing system for immersion cooling. These modular adapters may be used as part of converting an information processing system originally designed for air cooling into an immersion ready state and may further optimize the system for immersion cooling beyond the baseline conversion. Optimized, in this context, means that the system is configured to provide superior cooling performance to one or more components, such as the CPU, beyond that which would be provided by the system without the modular adapters (i.e., beyond what would have been provided if only the baseline conversion were done). The modular adapters may, in some examples, be designed to leverage aspects of existing air-cooled system designs, thereby allowing for easy deployment of the modular adapters in the system during the conversion process. For example, portions of the modular adapters may sit within spaces vacated by air cooling components removed during the conversion process and/or may attach and/or electrically connect to the system using the same mounting features and/or connectors previously used by now-removed air-cooling components.

The modular adapter includes a manifold coupled to a support, with the support configured to be received within a chassis of an information processing system. More particularly, the modular adapter may be configured to be installed in an empty volume created by removing air-cooling components such as fans, baffles, and complex heat sinks. This can allow an information processing system that was configured for air cooling to be reconfigured for immersion cooling, and particularly to be converted to immersion cooling while maintaining or increasing the efficiency of cooling over selected high heat components, such as CPUs. By reconfiguring an existing information processing system, development and equipment costs associated with building a new server are reduced.

In some examples, a modular adapter includes a support structure having a base and a pair of arms extending from the base. Each arm may include openings to engage with fasteners on a chassis. In some examples, the support structure may be coupled to the chassis at a location where a fan baffle or fan shroud would be coupled in the system when the system was air cooled. Thus, the support structure is installable within a volume created by removal of air-cooling components, such as fans and fan baffles.

A manifold may be coupled to the support structure. The manifold may be located such that fluid through the manifold may be directed over one or more hot components within the information processing system. An intake valve on the manifold may allow fluid to be directed through the manifold and over the various components of the system.

More particularly, the manifold may be coupled to a pump at the intake valve. In some examples, the coupling may be direct (i.e., the pump may be directly coupled to the manifold intake valve), while in other examples, the intake valve may be coupled to the pump via tubing. The pump may allow additional coolant fluid to be directed over selected hot components by moving the fluid through the manifold, thus increasing the amount of cooling of the various hot components beyond what is provided by the immersion in the coolant fluid.

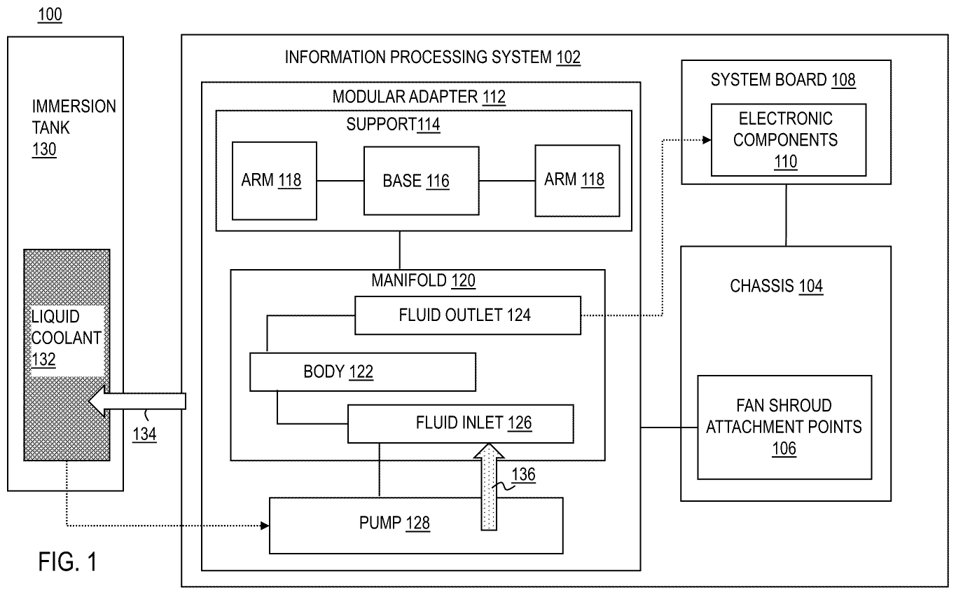

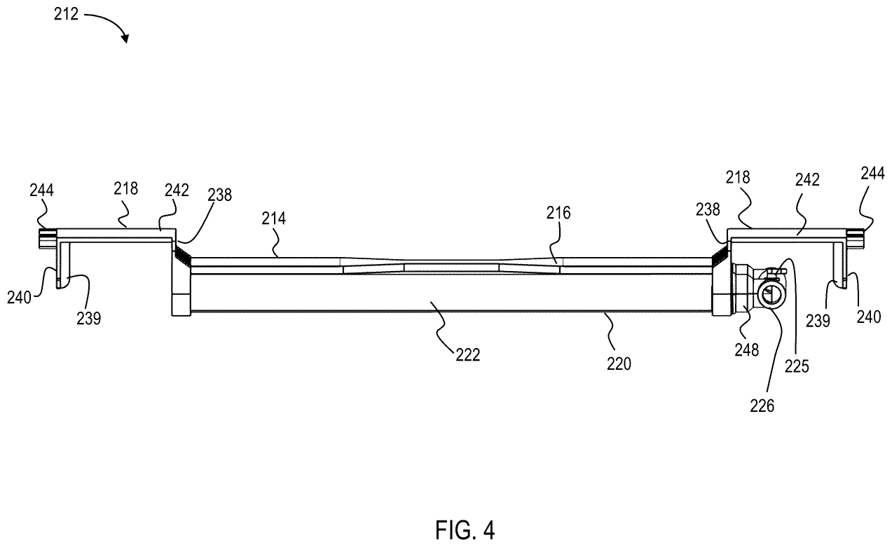

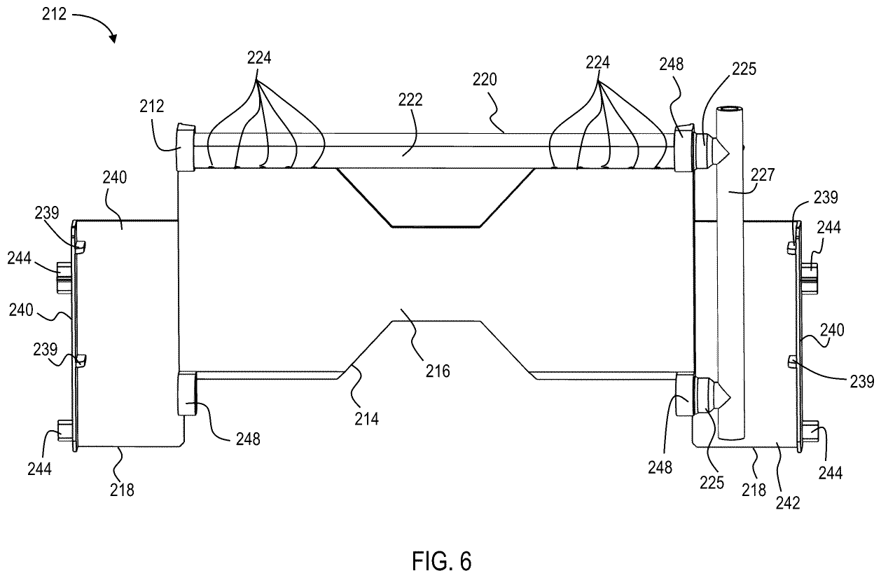

These and other examples will be described in greater detail below in relation to FIGS. 1-9.

FIG. 1 illustrates an example system 100. FIG. 1 is schematic in nature, and it should be understood that FIG. 1 is not intended to illustrate specific shapes, dimensions, positional relationships, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Certain positional relationships are indicated by thick white-filled arrows. Motion of coolant is indicated by dotted-line arrows, including a thick dot-filled arrow.

System 100 includes an information processing system 102. Information processing system 102 may be a server, although examples are not so limited. Information processing system 102 may include a chassis 104. Chassis 104 may include components such as a base, side walls, and a cover. Chassis 104 may further include fan shroud attachment points 106. Fan shroud attachment points 106 may be disposed on a side of chassis 104 and may allow a fan shroud (not shown) to be coupled to chassis 104.

A system board 108 may be supported by chassis 104. The system board 108 may be a main logic board that includes electronic components 110 coupled thereto. Electronic components 110 may include a central processing unit (CPU), a memory, and other core components (not illustrated), but examples are not so limited and any system board may be used.

A modular adapter 112 may be coupled to chassis 104 at the fan shroud attachment points 106. Modular adapter 112 may include a support 114, a manifold 120, and a pump 128, which together allow information processing system 102 to be cooled via direct liquid cooling.

Support 114 may include a base 116, which may be generally planar such that, when modular adapter 112 is coupled to chassis 104, base 116 is substantially parallel to system board 108. A pair of side arms 118 may extend from base 116. In some examples, side arms 118 may be disposed opposite and parallel to one another, with base 116 extending between arms 118. This may allow side arms 118 to engage with chassis 104. More particularly, side arms 118 may include attachment features to couple to fan shroud attachment points 106, allowing modular adapter 112 to be coupled to chassis 104.

A manifold 120 may be coupled to support 114. As used herein, a manifold refers to a volume that receives an input and distributes the input to multiple outputs. Manifold 120 may include a manifold body 122, which may define a volume through which an input, such as a coolant liquid, can flow. Manifold body 122 may be fluidically coupled to a fluid outlet 124. Fluid outlet 124 may be integrally formed within manifold body 122; however, examples are not so limited.

Manifold body 122 may further be coupled to a fluid inlet 126. Fluid inlet 126 may be fluidically coupled with fluid outlet 124 via the manifold body 122, allowing fluid to flow into the fluid inlet 126, through the manifold body 122, before exiting at the fluid outlet 124. In some examples, the fluid inlet 126 may include a valve, although examples are not so limited and other inlet structures may be used.

Modular adapter 112 may further include a pump 128. As used herein, a pump refers to a mechanical device that uses suction or pressure to move liquids from one space to another. As shown in FIG. 1, pump 128 may be coupled to fluid inlet 126, such that pump 128 may move a liquid, such as liquid coolant 132, through manifold 120.

System 100 may further include an immersion tank 130 including liquid coolant 132 held in a liquid-holding portion of the tank 130 to create a pool of liquid coolant 132. The liquid-holding portion of the tank 130 may be configured to receive information processing system 102 such that information processing system 102 is immersed in the pool of liquid coolant 132. As used herein, “immersed” means that at least some of the components are submerged in the liquid coolant 132. For example, only a subset of the electronic components 106 may be submerge in the liquid coolant 132. In some examples, the system board 108 and at least some of the electronic components 106 may be submerged in the liquid coolant 132. In other examples, the entirety of each information processing system 102 may be fully submerged. In other examples, a small portion of a system 102, such as a support bracket which supports the system, may protrude out of the liquid coolant 132. The immersion of system 102 in the liquid coolant 132 is shown by arrow 134.

The coolant 132 may be an electrically non-conducting material that is liquid at room temperatures, such as dielectric fluid. Immersion of information processing system 102 into liquid coolant 132 allows heat generated by electronic components 110 to be removed from the information processing system 102. More particularly, the coolant 132 absorbs heat from components of the system, via convection, and releases the heat externally from the system. In some examples, the coolant 132 may be a single-phase coolant, meaning it is engineered to absorb heat and circulate it through the immersion tank 130. This circulation may include transferring the absorbed heat to a heat exchanger (not shown in FIG. 1) before being circulated back through the immersion tank 130, thus allowing liquid coolant 132 to be continually moved over the information processing system 102. The heat exchanger may allow removal of heat from the liquid coolant 132 by means of a secondary coolant loop (not shown in FIG. 1). In other examples, the coolant 132 is a two-phase coolant, meaning it is engineered to transport heat by changing between liquid and vapor (gas) phases during operation of the device. In such examples, the coolant 132 has a boiling point which is near a desired operating temperature of the electronic components 110, which means that the electronic components 110 can bring the coolant 132 to boiling during operation. This boiling absorbs heat from the components and allows the heat to be dissipated via interaction of coolant 132, in vapor form, with a heat sink or other heat dissipating structures (not shown).

When information processing system 102 is immersed in liquid coolant 132, pump 128 may be configured to move liquid coolant 132. More particularly, pump 128 may draw liquid coolant 132 from the pool in the immersion tank 130 to fluid inlet 126. Liquid coolant 132 may then move through manifold body 122 and exit at fluid outlet 124. In some examples, fluid outlet 124 may direct liquid coolant 132 over electronic components 110 on system board 108. More particularly, fluid outlet 124 may be oriented to flow over selected electronic components 110. For example, fluid outlet 124 may be positioned to allow liquid coolant 132 to flow over high-temperature components, such as a CPU or a memory, thus allowing additional liquid coolant 132 to be moved over components, increasing the cooling of these components.

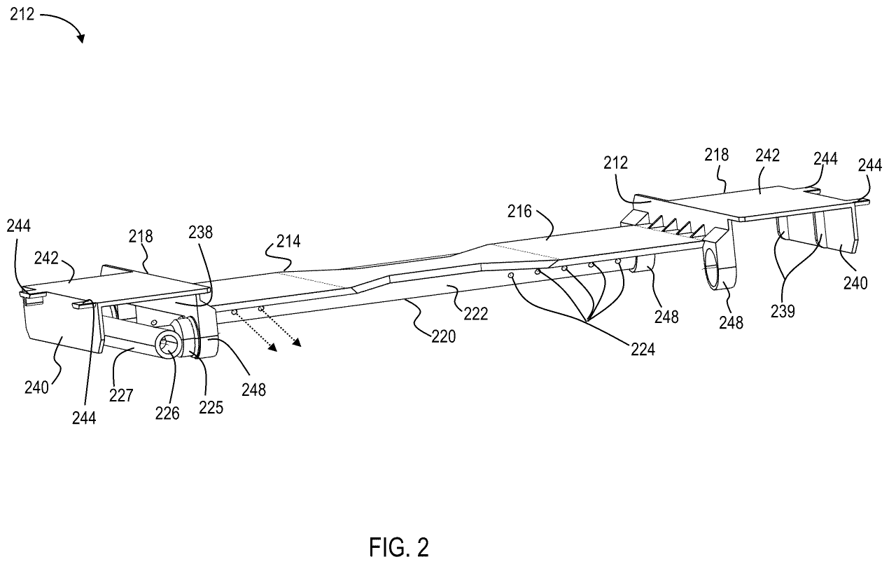

Turning to FIGS. 2-6, an example modular adapter 212 is shown. Modular adapter 212 may be one implementation example of modular adapter 112 shown in and described with respect to FIG. 1 and may be used in a system such as system 100, described with respect to FIG. 1. Modular adapter 212 thus comprises components which correspond to (i.e., are implementation examples of) components of the modular adapter 112, and the correspondence between such components is indicated herein by the components having reference numbers with the same last two digits, such as 122 and 222. Aspects of the modular adapter 112 and its components described above may also be applicable to the modular adapter 212 and its corresponding components, but the modular adapter 112 and its components are not limited to the modular adapter 212 and its components, which are just one example of how the modular adapter 112 may be implemented. In some instances, aspects of the modular adapter 112 already described above, which are also applicable to the modular adapter 212, are not described below to avoid duplicative description.

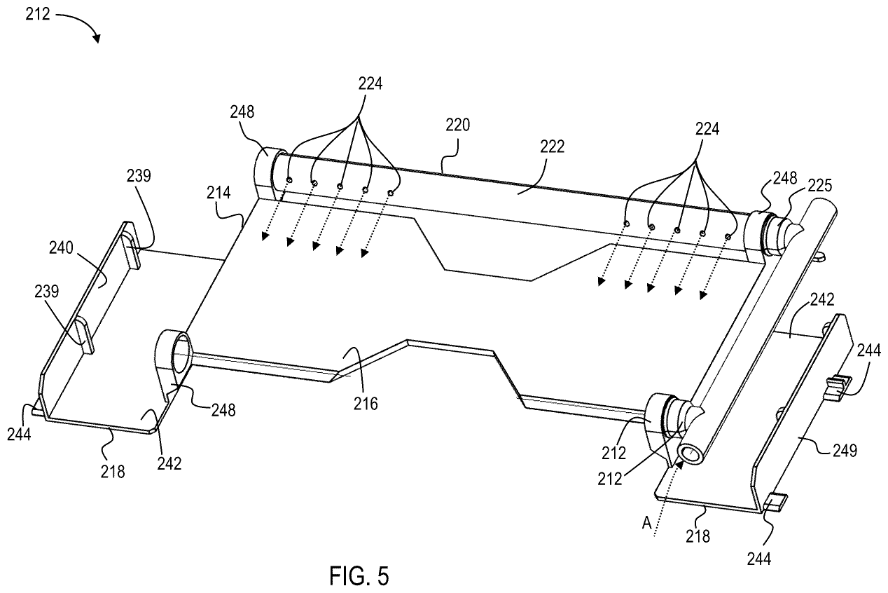

Modular adapter 212 includes a support 214. Support 214 includes a base 216. A pair of side arms 218 extend from base 216, with base 216 separating side arms 218. Each side arm 218 includes a first vertical portion 238 adjacent to base 216 and a second vertical portion 240 parallel to and spaced apart from first vertical portion 238. Top portion 242 extends between and connects first vertical portion 238 and second vertical portion 240, with top portion 242 being substantially planar and generally parallel to base 216. In addition, as shown in FIG. 5, brackets 239 extend along an inner surface of second vertical portion 240 to the top portion 242 to provide additional structure and support for second vertical portion 240.

A plurality of attachment features 244 extend from each arm 218. Attachment features 244 may be integrally formed with arm 218 or may be formed separately and subsequently attached. Attachment features 244 extend outwardly from top portion 242 and are configured to mate with corresponding attachment features on a chassis. More particularly, attachment features 244 are configured to mate with fan shroud attachment points, allowing modular adapter 212 to be installed in a chassis in the volume otherwise occupied by the fan shroud. In some examples, attachment features 244 are tabs configured to engage with complementary openings in the chassis by, e.g., a snap fit or a friction fit; however, examples are not so limited and attachment features 244 may be coupled via other types of attachments.

Brackets 248 are coupled to base 216, and in some examples are integrally formed with base 216. As shown in FIG. 5, brackets 248 include an opening configured to receive a component, such as manifold 220, to the component to support 214. Brackets 248 may be disposed at the corners of base 216, as shown in FIG. 5; however, examples are not so limited and other configurations of brackets 248 may be used.

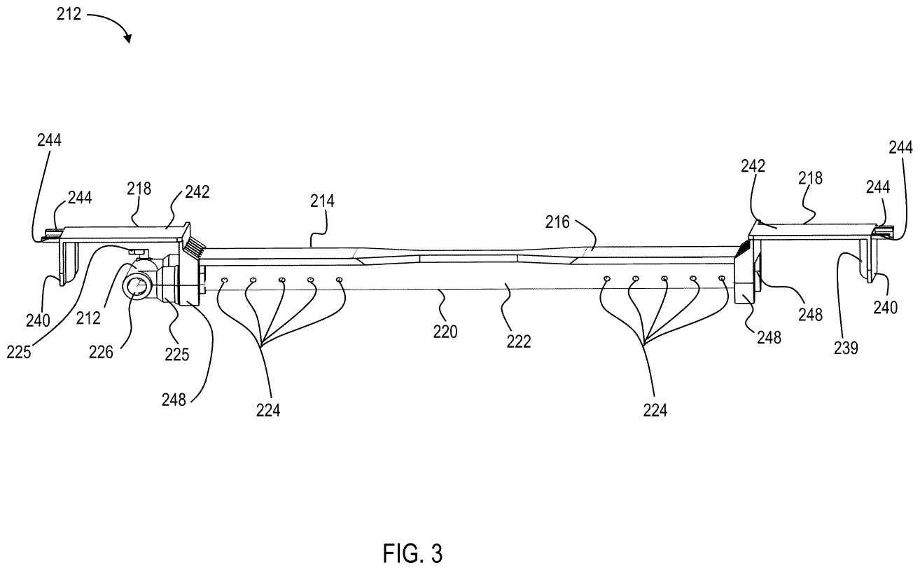

Manifold 220 is coupled to support 214 at two of the brackets 248 such that manifold 220 extends downwardly from base 216, as shown in, e.g., FIG. 2. More particularly, manifold body 222 extends between brackets 248 along the length of base 216, such that manifold body 222 is parallel to the length of base 216. Manifold body 222 includes a plurality of fluid outlets 224. As shown in FIGS. 3 and 5 in particular, fluid outlets 224 are formed as openings within manifold body 222, with fluid outlets 224 oriented to direct fluid such as a liquid coolant outward from manifold body 222. The direction of fluid flow from fluid outlets 224 is shown in FIGS. 2 and 5 by dotted line arrows extending from the fluid outlets 224. Ten fluid outlets 224 are shown in FIG. 5, however, examples are not so limited and more or fewer fluid outlets 224 may be used. In addition, as shown in FIG. 5, fluid outlets 224 are disposed linearly along a longitudinal axis of the manifold body 222, with the fluid outlets 224 disposed at each end of the manifold body 222. However, fluid outlets 224 may be disposed elsewhere on the manifold body 222 and in other orientations with respect to the longitudinal axis of manifold body 222. In addition, fluid outlets 224 may be extended along more of the length of manifold body 222 than is shown in FIG. 5.

Manifold 220 further includes a fluid inlet 226, which is fluidically coupled to manifold body 222 by an inlet pipe 227. Inlet pipe 227 is coupled to support 214 at attachment points 225, allowing inlet pipe 227 to be positioned relative to manifold 220 and secured to prevent movement relative to the support 214. As shown in FIG. 5, attachment points 225 are coupled to brackets 248 and extend out from body 216, allowing inlet pipe 227 to be coupled to support 214 parallel to a width of the body 216. Although not shown in FIGS. 2-6, inlet pipe 227 includes an opening where the inlet pipe 227 is coupled to manifold 220 to allow liquid coolant to flow from the fluid inlet 226, through the inlet pipe 227, and to the fluid outlets 224.

As shown in FIG. 5, coolant liquid enters fluid inlet 226, depicted by the dotted line arrow labeled A. Due to being coupled to inlet pipe 227, fluid inlet 226 is positioned such that coolant liquid entering fluid inlet 226 at A is drawn from a cooler portion of the coolant liquid (i.e., not adjacent to a heated component). n some examples, fluid inlet 226 is coupled to a pump (not shown in FIG. 5) to assist in directing coolant liquid into fluid inlet 226 and through inlet pipe 227. Coolant liquid then flows through inlet pipe 227 and into manifold 220, where it flows out of manifold body 222 at fluid outlets 224. The outward flow of coolant liquid at fluid outlets 224 is indicated by the dotted line arrows extending from fluid outlets 224. Because the coolant liquid exiting the fluid outlets 224 was drawn in from a cooler portion at fluid inlet 226, the coolant liquid exiting the fluid outlets 224 avoids being “pre-heated” by flowing over additional heat dissipating components, thus maximizing the amount of heat able to be removed by the coolant liquid. In this manner, coolant liquid is moved through modular adapter 212 when the modular adapter 212 is installed in a system that is immersed in a cooling liquid.

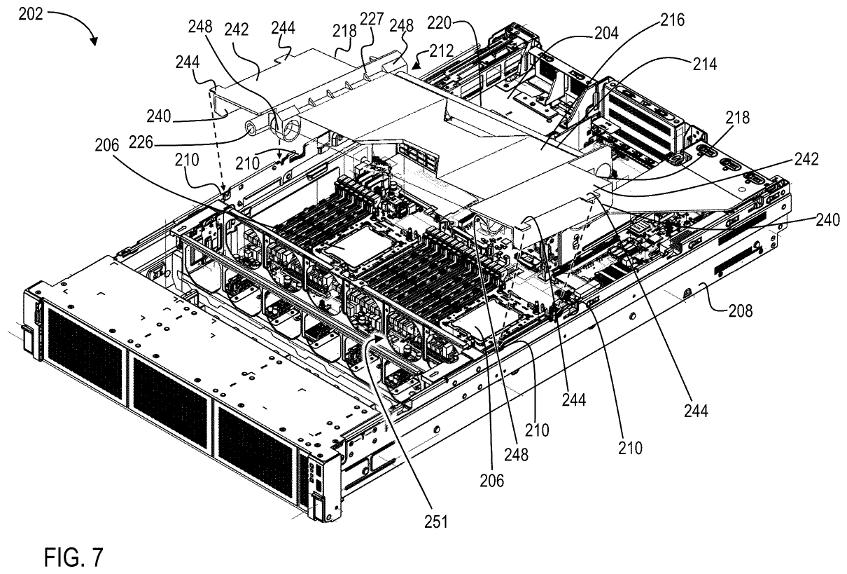

FIG. 7 is a perspective view of an information processing system 202 in which the modular adapter 212 described above may be used. Information processing system 202 includes a chassis 208 supporting a system board 204. System board 204 includes a plurality of electronic components 206 coupled thereto. While two electronic components 206 are shown in FIG. 7, examples are not so limited and more or fewer electronic components 206 may be present. Electronic components 206 may be a processor such as a CPU, a memory, or any other components. Chassis 208 may further include a plurality of fan shroud attachment points 210 formed as part of the chassis 208. As shown in FIG. 7, fan shroud attachment points 210 may be disposed on side walls of chassis 208, although examples are not so limited. Fan shroud attachment points 210 may be configured to mate with a fan shroud (not present in FIG. 7) to help direct air in an air-cooled system. However, as shown in FIG. 7, a fan shroud is not present, allowing modular adapter 212 to be installed in information processing system 202 such that modular adapter 212 occupies the space otherwise reserved for a fan shroud. It should be understood that, while FIG. 7 does not show modular adapter 212 in an installed position, modular adapter 212 is configured to engage with the chassis 208 at the fan shroud attachment points 210 and that, in the engaged state, modular adapter is disposed above system board 204 and electronic components 206.

More particularly, modular adapter 212 includes a support 214, with the support further comprising a base 216 and a pair of side arms 218. Side arms 218 include attachment features 244 disposed as part of a top portion 242 of side arms 218 and configured to engage with the fan shroud attachment points 210, as indicated by the dashed line arrows extending between each attachment feature 244 and a corresponding fan shroud attachment point 210, allowing modular adapter 212 to be installed within information processing system 202.

Base 216 of support 214 is substantially parallel to system board 204 when modular adapter 212 is installed within information processing system 202, with side arms 218 extending away from base 216. Side arms 218 include a first vertical portion (not shown in FIG. 7), and a second vertical portion 240 extending from top portion 242. In an installed position, second vertical portion 240 is adjacent to a side wall of chassis 208.

A manifold 220 is coupled to support 214 at brackets 248 such that, in an installed position of modular adapter 212 at chassis 208, fluid outlets (not shown in FIG. 7) in the manifold 220 are disposed such that the fluid outlets face electronic components 206. Manifold 220 is fluidically coupled to fluid inlet 226 via inlet tube 227. Thus, liquid, such as cooling liquid, entering fluid inlet 226 flows through inlet tube 227 and into manifold 220 before exiting at fluid outlets. In this manner, additional cooling liquid can be directed to flow towards or over one or more of the electronic components 206, providing additional cooling to the electronic components 206.

Fluid inlet 226 is coupled to a pump, not shown in FIG. 7. In some examples, the pump is disposed in an area 251 configured to receive a fan cage in an air-cooled system. The pump is further configured to be electronically connected to the system board at a power supply connector on the system board. In some examples, the pump is configured to couple to a fan power supply connector, although examples are not so limited. The power supply connector may also serve as a signal function. For example, the system board, via the power supply connector, may control the pump speed, and the pump may relay a functional status to the system board. Moreover, in examples where the power supply connector controls the speed of the pump, such control allows for closed-loop adaptive control of the temperature of at least one electronic component 206. Said differently, if a particular electronic component 206 is running above a desired temperature, the system board 204 is able to signal the pump to increase flow of coolant liquid through fluid inlet 226 and out fluid outlets 224, thus increasing the cooling over the electronic component 206.

When information processing system 202 is immersed in an immersion tank having a pool of liquid coolant, such as immersion tank 130 having liquid coolant 132, described with respect to FIG. 1, the pump helps move liquid coolant into the fluid intake 226 to direct the additional liquid coolant over the electronic components 206 via the fluid outlets. Thus, even when information processing system 202 is immersed in the liquid coolant to provide system cooling, certain electronic components are able to receive additional cooling, allowing information processing system 202 to remain at an operating temperature that is unlikely to cause heat-related damage to the system components.

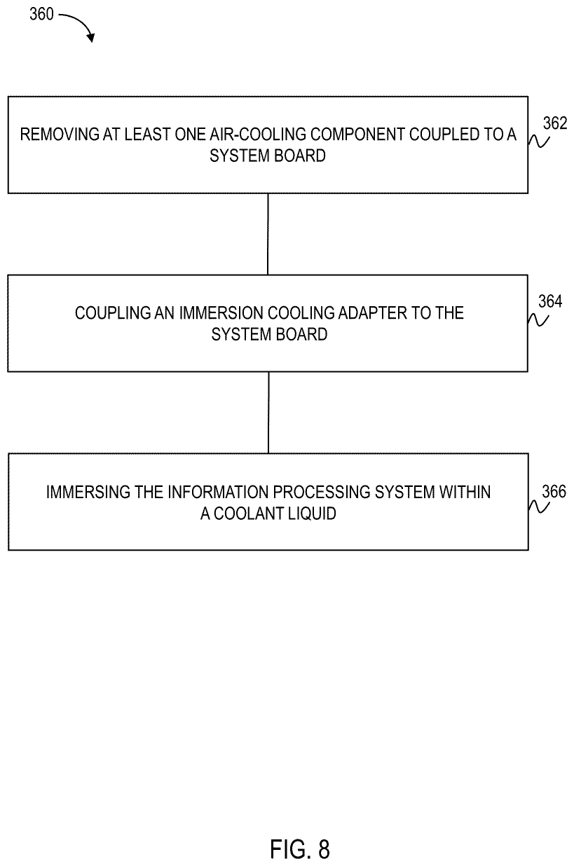

FIG. 8 is a method 360 for adapting a system to include a modular adapter. At 362, method 360 includes removing at least one air-cooling component coupled to a system board. The air-cooling component may be a fan shroud, a fan, or any other component used in an air-cooled system. Removal of the at least one air-cooling component creates an available volume on the system board. That is, by removing at least one air-cooled component, the system board has an empty space which used to be occupied by the at least one air-cooled component.

At 364, method 360 includes coupling an immersion cooling adapter to a chassis. More particularly, coupling an immersion cooling adapter to a chassis includes coupling a support including a manifold to the chassis at an attachment feature on the chassis. The attachment feature on the chassis may correspond to an attachment feature of the air-cooling component removed at 362. For example, as described with respect to FIGS. 1 and 7 in particular, the attachment feature on the chassis may be a fan shroud attachment feature, although examples are not so limited. When the immersion cooling adapter is coupled to the chassis, the immersion cooling adapter is disposed within the available volume on the system board. Said differently, immersion cooling adapter is configured to occupy the space originally occupied by the at least one air-cooling component, which was removed at 362.

Coupling an immersion cooling adapter to the chassis further comprises coupling a pump to a power supply on the system board. The pump is then fluidically coupled to the manifold such that the pump can move liquid to the manifold. In some examples, the pump is fluidically coupled to the manifold at a fluid inlet.

At 366, method 360 includes immersing the information processing system within a coolant liquid. More particularly, immersing the information processing system within a coolant liquid at 366 comprises immersing at least a portion of the system board including the immersion cooling adapter within the coolant liquid. This immersion allows the pump to move coolant liquid to the manifold, providing cooling for components on the system board. In some examples, the coolant liquid is a dielectric liquid, although examples are not so limited.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a system board comprising electronic components;
a chassis supporting the system board and comprising fan shroud attachment points configured to receive a fan shroud attached thereto; and
a modular adapter for immersion cooling, comprising:
a support having a base and a pair of side arms, the side arms configured to couple to the chassis at the fan shroud attachment points in lieu of the fan shroud;
a manifold coupled to the base; and
a pump operatively coupled to the manifold and configured to, in a state of the information processing system immersed in a pool of liquid coolant in an immersion cooling tank, move a flow of the liquid coolant, drawn from the pool, through the manifold, the manifold configured to output the flow of the liquid coolant back into the pool as one or more output streams.

2. The information processing system of claim 1, wherein the modular adapter is configured to couple with the chassis in a space created by removal of at least one air-cooling component.

3. The information processing system of claim 1, wherein each side arm of the pair of side arms further comprises:
a first vertical portion coupled to the base of the support and extending away from the base of the support;
a second vertical portion offset from and parallel to the first vertical portion; and
a top portion disposed between and connecting the first vertical portion and the second vertical portion.

4. The information processing system of claim 3, wherein the top portion further comprises a plurality of attachment features to engage with the chassis at the fan shroud attachment points.

5. The information processing system of claim 1, wherein the manifold further comprises:
a fluid inlet;
a manifold body coupled to the fluid inlet and defining a volume; and
a plurality of outlets in the manifold body and fluidically coupled to the fluid inlet, the plurality of outlets configured to output the one or more output streams.

6. The information processing system of claim 1, wherein the pump is electrically connected to the system board at a power supply connector disposed on the system board.

7. The information processing system of claim 6, wherein:
the power supply connector further comprises a signal connection to control a speed of the pump at the system board; and
the speed of the pump is regulated to maintain a desired temperature of at least one electrical component.

8. The information processing system of claim 1, wherein, in an installed position, the support is positioned above the system board and over at least one electronic component coupled to the system board.

9. The information processing system of claim 8, wherein an inlet of the pump is fluidically coupled with the pool of the liquid coolant by a tube coupled to the inlet and extending into the pool of the coolant fluid.

10. The information processing system of claim 8, wherein the pump is disposed in an area to receive a fan cage in lieu of the fan cage.

11. The information processing system of claim 1, wherein the manifold is configured such that, on condition of the side arms being coupled to the chassis, the one or more output streams are directed to flow towards or over one or more of the electronic components.

12. An information processing system, comprising:
a system board comprising a plurality of information processing components and at least one air-cooling component, wherein the system board includes a volume defined by removal of the at least one air-cooling component;
a chassis supporting the system board; and
an immersion cooling adapter, comprising:
a support having a base and a pair of side arms, the support configured to couple to the system board at attachment points for the at least one cooling component;
a manifold coupled to the base, the manifold further comprising a fluid inlet, a manifold body coupled to the fluid inlet, and a plurality of fluid outlets formed within the manifold body; and
a pump operatively coupled to the manifold and configured to move a coolant fluid through the manifold,
wherein the information processing system is configured to be immersed in the coolant fluid in a state of the immersion cooling adapter installed at the system board.

13. The information processing system of claim 12, wherein the pump is fluidically coupled with the coolant fluid in a state of the information processing system being immersed in the coolant fluid.

14. The information processing system of claim 13, wherein the pump is fluidically coupled with the coolant fluid via a tube coupled to the pump and extending to a volume of coolant fluid outside the chassis.

15. The information processing system of claim 12, wherein the support couples to the system board by engagement of the attachment points on the system board with corresponding attachment points on the pair of side arms.

16. The information processing system of claim 12, wherein the pump is electrically coupled with a power supply on the system board such that the pump moves coolant fluid through the manifold.

17. The information processing system of claim 12, wherein the plurality of fluid outlets are oriented such that fluid passing through the plurality of fluid outlets is directed over at least one particular component of the plurality of information processing components.

18. A method for adapting an information processing system for immersion cooling, comprising:
removing at least one air-cooling component coupled to a system board, wherein removing at least one air-cooling component creates an available volume on the system board;
coupling an immersion cooling adapter to a chassis, wherein the immersion cooling adapter is coupled to the chassis such that the immersion cooling adapter is disposed within the available volume; and
immersing the information processing system within a coolant liquid.

19. The method of claim 18, wherein coupling an immersion cooling adapter to the chassis further comprises:
coupling a support including a manifold to the chassis at an attachment feature on the chassis;
coupling a pump to a power supply on the system board; and
fluidically coupling the pump to the manifold.

20. The method of claim 18, wherein immersing the information processing system within a coolant liquid further comprises immersing at least a portion of the system board including the immersion cooling adapter within the coolant liquid.
